(19) United States
(12) Patent Application Publication
(10) Pub. No.: US 2009/0035701 A1
(43) Pub. Date: Feb. 5, 2009

(54) Photoresist and pattern-forming process using the same

(76) Inventors: Chau-Kuang Liau, Jhongli City (TW); Wen-Wei Chou, Bade City (TW); Jung-Kang Wu, Taoyuan City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/905,996

(22) Filed: Oct. 9, 2007

(30) Foreign Application Priority Data
Aug. 3, 2007 (TW) 96128758

(51) Int. Cl. G03C 1/77; G03F 7/20

(52) U.S. Cl. 430/286.1; 430/270.1; 430/327

(57) ABSTRACT

A photolithography process using a photoresist is as following. A substrate is provided for coating a photoresist thereon to form a photoresist layer and the photoresist is formed by mixing photocatalyst particles and polymer binder in a solvent. The photoresist layer is well-adhesive and has good mechanical strength. A light is illuminated on the photoresist layer through a photo mask having a pre-designed pattern thereon. Then, the portion of the photoresist layer where the light projects is removed by water or another environment-friendly solvent so as to reduce the harmful waste produced in the processes.

### BACKGROUND OF THE INVENTION

1. Field of the Invention

The present invention relates to a photoresist and a process using the same and in particular to a photoresist composed of photocatalyst particles and polymer binder and the process using the same.

2. Description of Prior Art

Depending that the technology of IC, such as the integrity of IC and the operation rate of IC is increasing, lithography process takes a very important role on the processes for manufacturing IC. The IC manufacturing industry always focuses on the resolution of the lithography process so as to reduce the line-width of the semiconductor device.

The coated quality of the photoresist controls the resolution of the lithography process. Photoresist is a light-sensitive material and in the process, i.e. the exposing process, the photoresist reacts with the light through the mask. In detail, the photoresist is composed of photo-active-compound, resin, solvent and surfactants (SFA) and when the photoresist is irradiated by light, the photo-active-compound is transformed into acidic product. The acidic product takes a neutralization reaction with the developer.

However, many kinds of the acidic and alkali chemicals, organic solvent or harmful gas are used with the photoresist in lithography process. For instance, the organic solvent, such as acetone, dichloromethane, chloroform are commonly used for removing the photoresist and the product after etching process. The waste water of the process is composed of xylene, butyl acetate or toluene so that the waste contaminates our environment. Furthermore, the components of the waste take reactions with each other and it is necessary to handle the waste carefully. On the other hand, the photoresist is a photo-active material and the wavelength of the place to reserve the photoresist must be strictly controlled so as to protect the photoresist.

Accordingly, a “photo-lithography workshop” is employed for reserving the photoresist to prevent the photoresist from the light so that the manufacturing cost is further increasing. Moreover, the chemicals used for removing the photoresist are harmful for our environment, and the chemicals may cause damage to the environment.

Therefore, in view of this, the inventor proposes the present invention to overcome the above problems based on his expert experience and deliberate research.

### SUMMARY OF THE INVENTION

The primary object of the present invention is provided for a photoresist and a pattern-forming process using the same. The photoresist is composed of a plurality of photocatalyst particles and a polymer binder and the photoresist is applied for coating adhesively on a substrate so as to form a photoresist layer with high mechanical strength.

The other object of the present invention is to provide a photoresist and a pattern-forming process using the same. The photoresist can be removed from the substrate by environment-friendly solvent, such as water, after the photoresist is irradiated by light so that the harmful waste of the processes using the photoresist is reduced. Moreover, the environment is protected from the harmful chemicals.

A further object of the present invention is to provide a photoresist and a pattern-forming process using the same. The composition of the photoresist in the present invention is stable in an ordinary condition. In other words, it is not necessary to preserve the photoresist in the photo-lithography workshop. On the other hand, the water is used for the photoresist instead of expensive chemicals. Accordingly, the manufacturing cost is further reduced.

In order to achieve the above object, the present invention provides a photoresist for producing a substrate with a pattern thereon. The photoresist comprises: a plurality of photocatalyst particles; a polymer binder; and a solvent. The photocatalyst particles and the polymer binder are mixed in the solvent with a predetermined weight ratio.

In order to achieve the above object, the present invention provides a process using the photoresist in accordance with the present invention. The process includes the following steps:
(a) providing a substrate;
(b) providing a photoresist layer on the substrate by coating the photoresist made of a plurality of photocatalyst particles and a polymer binder;
(c) providing a mask having a predetermined pattern;
(d) projecting light emitted from a light source to the photoresist layer through the mask; and
(e) removing the light-exposed region of the photoresist layer by the solvent.

The present invention provides a photoresist and a pattern-forming process using the same. The present invention provides an environment-protecting process to achieve the manufacture of semiconductor. The light-sensitive reaction of the photocatalyst particle is activated by light exposure to decompose the polymer binder so that the exposed region of the photoresist layer can be removed by water or alcohol. The above process replaces for the traditional process which produces more harmful waste so as to protect the environment.

In order to better understand the characteristics and technical contents of the present invention, a detailed description thereof will be made with reference to the accompanying drawings. However, it should be understood that the drawings and the description are illustrative but not used to limit the scope of the present invention.

### BRIEF DESCRIPTION OF THE DRAWINGS

FIG. 1 is a flow chart showing the process using the photoresist according to the present invention;

FIG. 2A is a cross-sectional view showing the embodiment of forming a photoresist layer on a substrate according to the present invention;

FIG. 2B is a cross-sectional view showing the embodiment of providing a mask according to the present invention;

FIG. 2C is a cross-sectional view showing the embodiment of projecting light on the photoresist layer according to the present invention;

FIG. 2D is a cross-sectional view showing the embodiment of removing the exposed portion of the photoresist layer according to the present invention.

### DETAILED DESCRIPTION OF THE INVENTION

The invention discloses a photoresist applied for producing a substrate with a pattern thereon. The photoresist comprises a plurality of photocatalyst particles; a polymer binder; and a solvent. The photocatalyst particles and the polymer binder are mixed in the solvent with a predetermined weight ratio. The photocatalyst particle is made of titanium dioxide (TiO₂) or zinc oxide (ZnO), i.e. the TiO₂ particle or the ZnO particle. The size of the photocatalyst particle is nano scale, in other words, the diameter of the particle is in the nanometer scale. On the other hand, the polymer binder is selected from Poly(vinvl butyral) (PVB), Poly(methyl methacrylate) (PMMA), or Poly(vinyl alcohol) (PVA). However, materials of the photocatalyst particle or the polymer binder are not restricted to the above mentioned materials.

The photoresist is produced by the following steps. The first step is uniformly mixing the polymer binder and a solvent into a mixture, and then still placing the mixture for a predetermined time period. The second step is mixing the photocatalyst particles into the mixture and the photocatalyst particles and the polymer binder are mixed uniformly. In practice, the solvent is water or alcohol. Alternatively, the procedure can be replaced for mixing the photocatalyst particles with the solvent and then mixing the polymer binder with the solvent.

Furthermore, the photocatalyst particles are nano-scale ceramic particles. In the embodiment, the photocatalyst particles and the polymer binder are mixed of a weight ratio of 3:2, but the weight ratio is not restricted to the above ratio.

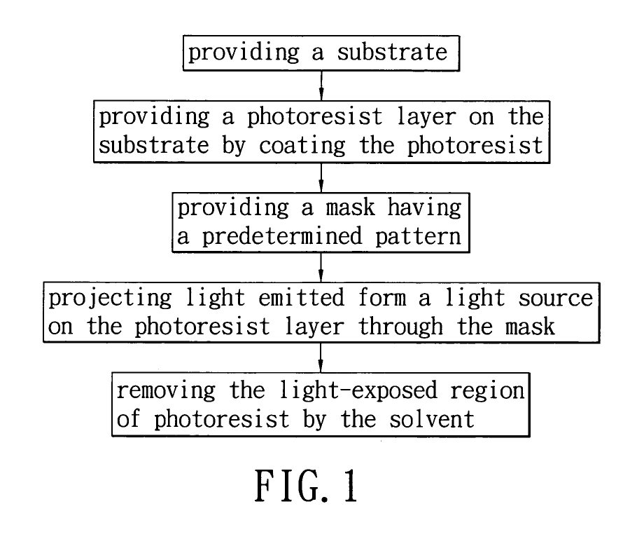

In addition, the present invention discloses a process using the photoresist and the process is provided for transforming a predetermined pattern on a substrate. Please refer to FIG. 1, the steps of the process includes:
(a). providing a substrate 1;
(b). providing a photoresist layer 2 on the substrate 1 by coating the photoresist made of a plurality of photocatalyst particles and a polymer binder;
(c) providing a mask 3 having a predetermined pattern 31;
(d) projecting light emitted form a light source to the photoresist layer 2 through the mask 3; and
(e) removing the light-exposed region of photoresist layer 2 by the solvent.

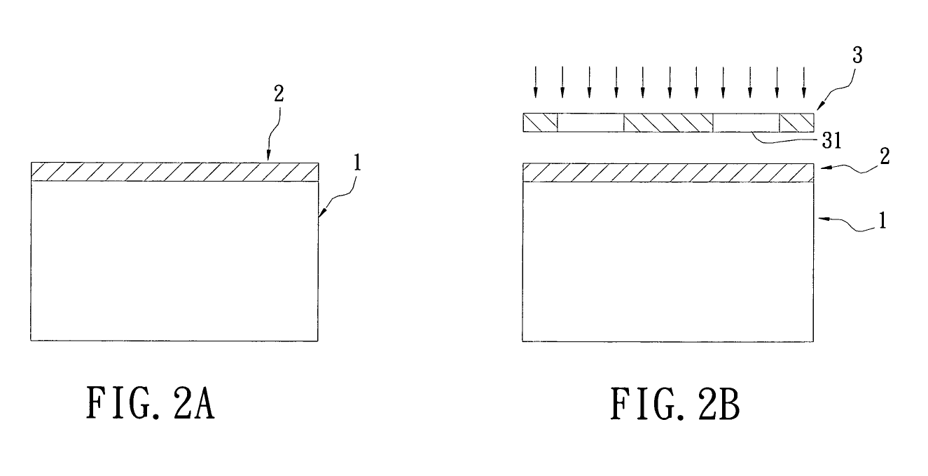

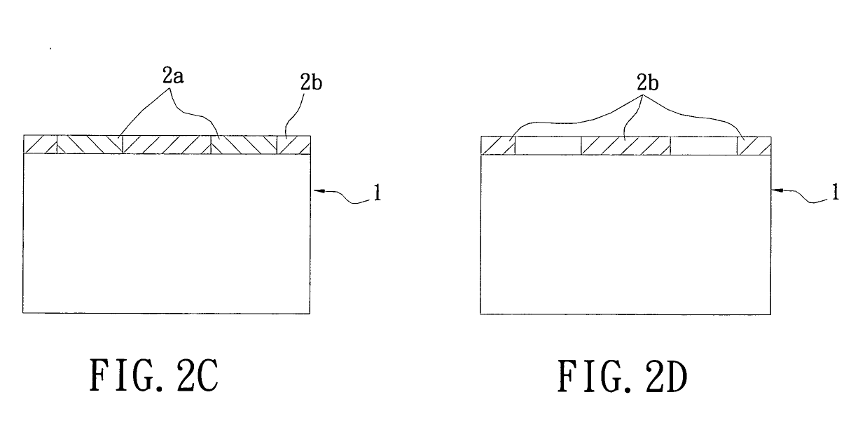

In detail, the substrate 1 is a glass substrate in the embodiment. However, the photoresist also can be employed for semiconductor substrates, such as silicon substrate. The photoresist made of a plurality of photocatalyst particles and a polymer binder is coated on the substrate 1 so as to form a photoresist layer 2 on the substrate 1 (FIG. 2A). However, persons of ordinary skill in the art should appreciate that the particular tools for below processes are intended to be practice and not to limit the present invention. After the coating step, the drying step is provided for removing the solvent of the photoresist layer 2 by heating method or a rotating method. The photoresist is adhesive firmly on the substrate 1 so as to form a photoresist layer 2 with high mechanical property after removing the redundant solvent. The photoresist layer 2 is provided for protecting the substrate 1 from the etching of the chemicals or plasma. In other words, it is necessary for the photoresist layer 2 to be attached firmly on the substrate 1 and further has high mechanical property. The photoresist layer 2 produced in the present invention has high mechanical property so that it can be applied for the etching or another process. Next step is providing a mask 3 having a predetermined pattern 31 thereon as shown in FIG. 2B. The predetermined pattern 31, as well as the physical, communicative, and/or electrical interconnections, are considered matters of design choice and are not material to the present invention. The photoresist is applied for forming the predetermined pattern 31 on the substrate 1 in accordance with the present invention. The photoresist layer 2 below the predetermined pattern 31 is exposed by the light through the mask 3. Moreover, the position of the mask 3 either contacts with the photoresist layer 2, or there is a space between the mask 3 and the photoresist layer 2.

Please refer to FIG. 2B again, light generated from a light source is emitted above the mask 3 and the light source can be an ultraviolet (UV) light source or a visible light source. The ultraviolet (UV) light is blocked by the mask 3 and simultaneously passes through the predetermined pattern 31 and projects on the photoresist layer 2. In the embodiment, ultraviolet (UV) light irradiates on the photoresist layer 2 at room temperature so as to activate the light-induced reaction of the photoresist layer 2 to decompose the polymer binder.

Please refer to FIG. 2C, after the photoresist layer 2 exposed in a predetermined time period, the light source and the mask 3 are removed. The photoresist layer 2 is marked in two portions, i.e. exposed portion 2a and non-exposed portion 2b. Due to the light-induced reaction of the photoresist layer 2, the chemical and physical properties of the exposed portion 2a differentiate from those of the non-exposed portion 2b. In exposed portion 2a, light-sensitive reaction of photocatalyst particles is induced by the irradiation of the light so that the polymer binder is decomposed by the light-sensitive reaction. Because the polymer binder is decomposed, the structure of the exposed portion 2a is thereby transformed to be loose so that the exposed portion 2a can be easily removed by the solvent.

At last, the step for removing the loose exposed portion 2a is processing. In the present invention, it is not necessary using the environment-harmful chemicals, such as hydrochloride chemicals. Alternatively, water or alcohol is employed for removing the exposed portion 2a on the substrate 1 (shown in FIG. 2D). After a drying step, the non-exposed portion 2b is firmly attached on the substrate 1. As mentioned above, a light-exposing step and a step for removing the exposed portion 2a are provided for forming the predetermined pattern 31 on the photoresist layer 2.

Furthermore, an etching process is used for forming the predetermined pattern 31 on the substrate 1 and then the substrate 1 is applied for manufacturing a semiconductor device.

To sum up, the present invention achieves the following advantages:

1. In accordance with the present invention, the light-sensitive reaction is induced after the photocatalyst particles irradiated by the light so that the polymer binder is decomposed by the light-sensitive reaction. Accordingly, the photoresist layer 2 is formed into two portions including exposed portion 2a and non-exposed portion 2b, thus the exposed portion 2a can be easily removed from the substrate 1 so as to form the predetermined pattern on the substrate 1.

2. The photoresist is attached firmly on the substrate 1 and the photoresist layer 2 can be applied for a manufacturing procedure of semiconductor.

3. The exposed portion 2a can be removed by an environment-friendly solvent, such as water or alcohol so that the harmful waste produced in the manufacturing procedure can be reduced.

4. The composition of the photoresist is stable and common in ordinary condition. The “photo-lithography workshop” applied for manufacturing process is not necessary for the photoresist of the present invention. Furthermore, the solvent using for the photoresist is environment-friendly solvent so that the cost for handling the processing waste is reduced.

5. The photoresist of the present invention can be extremely common for semiconductor industry, packaging industry, printing-circuit-board industry and TFT-LCD industry.

Although the present invention has been described with reference to the foregoing preferred embodiment, it will be understood that the invention is not limited to the details thereof. Various equivalent variations and modifications may occur to those skilled in this art in view of the teachings of the present invention. Thus, all such variations and equivalent modifications are also embraced within the scope of the invention as defined in the appended claims.

What is claimed is:

1. A photoresist for producing a substrate with a pattern thereon, the photoresist comprising:
a plurality of photocatalyst particles;
a polymer binder; and
a solvent;
wherein the photocatalyst particles and the polymer binder are mixed in the solvent with a predetermined weight ratio.

2. The photoresist according to claim 1, wherein the photocatalyst particle is made of titanium dioxide (TiO₂) or zinc oxide (ZnO).

3. The photoresist according to claim 2, wherein a size of the photocatalyst particle is nano scale.

4. The photoresist according to claim 1, wherein the polymer binder is poly (vinvl Butyral) (PVB), poly (methyl Methacrylate) (PMMA), or poly (vinyl alcohol) (PVA).

5. The photoresist according to claim 1, wherein the solvent is alcohol.

6. The photoresist according to claim 1, wherein the photocatalyst particles and the polymer binder are mixed of a weight ratio of 3:2 into the solvent.

7. A process using the photoresist of claim 1 comprising:
(a) providing a substrate;
(b) providing a photoresist layer on the substrate by coating the photoresist made of a plurality of photocatalyst particles and a polymer binder;
(c) providing a mask having a predetermined pattern;
(d) projecting light emitted form a light source to the photoresist layer through the mask; and
(e) removing a light-exposed region of the photoresist layer by a solvent.

8. The process according to claim 7, wherein the photoresist is made by following steps:
mixing the polymer binder and a solvent into a mixture;
still placing the mixture for a predetermined time period; and
mixing the photocatalyst particles into the mixture.

9. The process according to claim 8, wherein the photocatalyst particle is made of titanium dioxide (TiO₂) or zinc oxide (ZnO) and the polymer binder is poly (vinvl butyral) (PVB), poly (methyl methacrylate) (PMMA), or poly (vinyl alcohol) (PVA).

10. The process according to claim 7, wherein the light source is an ultraviolet (UV) light source or a visible light source.

11. The process according to claim 7, wherein after step (b) further comprises a drying step for removing the solvent on the photoresist layer.

12. The process according to claim 7, wherein the polymer binder is decomposed by a light-sensitive reaction of the photocatalyst particles in step (d).

13. The process according to claim 7, wherein water or alcohol is provided for removing the photoresist layer irradiated by the light.

14. The process according to claim 7, further comprising an etching step for forming the predetermined pattern onto the substrate.
